(19) United States
(12) Patent Application Publication
(10) Pub. No.: US 2014/0070261 A1
(43) Pub. Date: Mar. 13, 2014

(54) STACKED LED DEVICE WITH POSTS IN ADHESIVE LAYER

(71) Applicant: PHOSTEK, INC., Hsinchu City (TW)

(72) Inventors: Yi-An Lu, Chiayi City (TW); Heng Liu, Sunnyvale, CA (US)

(73) Assignee: PHOSTEK, INC., Hsinchu City (TW)

(21) Appl. No.: 14/077,625

(22) Filed: Nov. 12, 2013

Related U.S. Application Data
(62) Division of application No. 13/458,149, filed on Apr. 27, 2012.

(51) Int. Cl. H01L 33/36

(52) U.S. Cl. CPC H01L 33/36
USPC 257/99

(57) ABSTRACT

A semiconductor light emitting device includes a substrate and a first epitaxial structure over the substrate. The first epitaxial structure includes a first doped layer, a first light emitting layer, and a second doped layer. The first doped layer includes a first dopant type and the second doped layer includes a second dopant type. A second epitaxial structure includes a third doped layer, a second light emitting layer, and a fourth doped layer. An adhesive layer is between the first epitaxial structure and the second epitaxial structure. One or more posts are located in the adhesive layer. An electrode pattern is located on an upper surface of the second epitaxial structure, wherein the posts are located under electrodes in the electrode pattern.

### CROSS-REFERENCE TO RELATED APPLICATIONS

This application is a divisional of U.S. patent application Ser. No. 13/458,149, filed on Apr. 27, 2012, and entitled “STACKED LED DEVICE WITH POSTS IN ADHESIVE LAYER”.

### BACKGROUND

1. Field of the Invention

The present invention relates to a semiconductor light emitting component, and more particularly to a light emitting diode (LED) module and a method for manufacturing the LED module.

2. Description of Related Art

U.S. Pat. No. 7,575,340 to Kung et al. (“Kung ″340”), which is incorporated by reference as if fully set forth herein, describes conventional light projectors using gas discharge lamps as the optical engine of the projectors along with their deficiencies and how light source systems using light-emitting diode (LED) modules as the optical engine can overcome some of the problems. Conventional projectors (optical systems) that use gas discharge lamp light sources may be expensive and have short service lives. Gas discharge lamp light sources may also emit ultraviolet light, which requires isolation of the gas discharge lamp to inhibit damage due to the ultraviolet light. Gas discharge lamps are also not typically thought of as being environmentally friendly or a “green product” because of the energy usage of the lamps and the use of mercury in the lamps.

To overcome the problems with gas discharge lamps, Kung ″340 describes light source system 10 using three LED modules 12, 14, 16 as the optical engine, shown in FIG. 1. The light source system of Kung ″340, however, uses three separate, stand-alone sets of LED modules (e.g., one set each of red, blue, and green LED modules). The light from the three separate sets of LED modules is combined to provide the resultant light emitted from the light source system (e.g., light projector system). The use of multiple sets of LED modules and corresponding components (e.g., a diode lens cap and a primary lens unit) may, however, be bulky and more expensive. Thus, there is a need to reduce the size of the optical engine and potentially lower the cost for producing the light source system.

### SUMMARY

In certain embodiments, a semiconductor light emitting device includes a substrate with a first epitaxial structure over the substrate. The first epitaxial structure includes a first doped layer, a first light emitting layer, and a second doped layer. The first doped layer includes a first dopant type and the second doped layer includes a second dopant type. A second epitaxial structure includes a third doped layer, a second light emitting layer, and a fourth doped layer. An adhesive layer is between the first epitaxial structure and the second epitaxial structure. One or more posts are located in the adhesive layer. An electrode pattern is located on an upper surface of the second epitaxial structure, wherein the posts are located under electrodes in the electrode pattern.

### BRIEF DESCRIPTION OF THE DRAWINGS

Features and advantages of the methods and apparatus of the present invention will be more fully appreciated by reference to the following detailed description of presently preferred but nonetheless illustrative embodiments in accordance with the present invention when taken in conjunction with the accompanying drawings in which:

FIG. 1 depicts a prior art light source system using three LED modules as an optical engine.

FIG. 2 depicts a side-view representation of an embodiment of a horizontal light emitting diode (LED).

FIG. 3 depicts a simplified side-view representation of the embodiment of an LED showing a substrate, an n-doped layer, a p-doped layer, and a light emitting layer.

FIG. 4 depicts a side-view representation of an embodiment of a bottom LED with posts formed on the LED to be used in the stacked LED module.

FIG. 5 depicts a side-view representation of an embodiment of a top LED to be used in the stacked LED module.

FIG. 6 depicts a side-view representation of an embodiment of the top LED with the substrate removed from the bottom of the top LED to expose the bottom surface of the top LED.

FIG. 7 depicts a side-view representation of an embodiment with the top LED bonded to the bottom LED.

FIG. 8 depicts a side-view representation of an embodiment with a temporary substrate and an adhesive layer removed from the top LED to form the stacked LED module.

FIG. 9 depicts a side-view representation of an embodiment with electrodes formed on the stacked LED module.

FIG. 10 depicts a side-view representation of an embodiment of stacked LED module 150 with four electrodes formed on the stacked LED module.

FIG. 11 depicts a perspective view of an embodiment of the stacked LED module with each electrode located at one of the corners of the stacked LED module.

FIG. 12 depicts a side-view representation of an embodiment of a stacked LED module with three LEDs.

FIG. 13 depicts a side-view representation of an embodiment of a top LED bonded to a conductive substrate.

FIG. 14 depicts a side-view representation of an embodiment of the top LED bonded to the conductive substrate with the other substrate removed from the bottom of the top LED.

FIG. 15 depicts a side-view representation of an embodiment with the top LED bonded to the bottom LED and the conductive substrate.

FIG. 16 depicts a side-view representation of an embodiment with a substrate removed from the bottom LED to form the stacked LED module.

FIG. 17 depicts a top view representation of an electrode pattern on a top LED showing the location of posts under the electrode pattern.

While the invention is susceptible to various modifications and alternative forms, specific embodiments thereof are shown by way of example in the drawings and will herein be described in detail. The drawings may not be to scale. It should be understood that the drawings and detailed description thereto are not intended to limit the invention to the particular form disclosed, but to the contrary, the intention is to cover all modifications, equivalents and alternatives falling within the spirit and scope of the present invention as defined by the appended claims.

### DETAILED DESCRIPTION OF EMBODIMENTS

In the context of this patent, the term “coupled” means either a direct connection or an indirect connection (e.g., one or more intervening connections) between one or more objects or components.

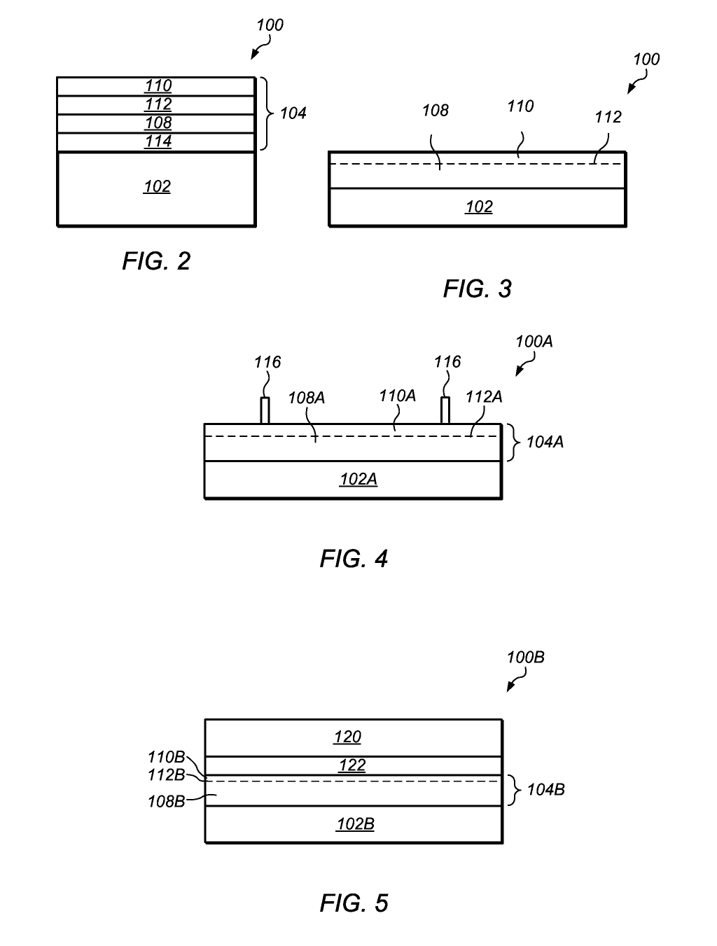

FIG. 2 depicts a side-view representation of an embodiment of horizontal light emitting diode (LED) 100. LED 100 includes epitaxial structure 104 on substrate 102. In certain embodiments, epitaxial structure 104 is grown from substrate 102 by a thin film deposition process (e.g., an epitaxial growth process). In certain embodiments, substrate 102 includes sapphire, germanium (Ge), silicon carbide (SiC), gallium arsenide (GaAs), zinc oxide (ZnO), or lithium aluminum oxide (γ-LiAlO₂). In some embodiments, substrate 102 is polar substrate, semi-polar substrate, or non-polar substrate. With sapphire or SiC, epitaxial growth of group-III nitride (e.g., GaN, InGaN, AlGaN, AlInGaN) can be achieved on substrate 102. In some embodiments, substrate 102 is a patterned substrate (e.g., a patterned sapphire substrate). In some embodiments, substrate 102 includes a reflective layer on the upper surface of the substrate. The reflective layer may include a distributed Bragg reflector (DBR), an omni-directional reflector (ODR), silver, aluminum, titanium, and/or other reflective metals.

In certain embodiments, during the epitaxy growth process, group-III nitride material is epitaxially grown up from substrate 102 to form n-type doped layer 108 and p-type doped layer 110. In certain embodiments, light emitting portion 112 is between n-type doped layer 108 and p-type doped layer 110. In some embodiments, epitaxial structure 104 includes undoped layer (not shown) between substrate 102 and n-type doped layer 108.

In some embodiments, a conducting layer is formed on top of p-doped layer 110. The conducting layer may be formed on top of p-doped layer 110 using, for example, a deposition process. In certain embodiments, the conducting layer is a substantially transparent conducting layer. The conducting layer may include, for example, indium tin oxide (ITO). In certain embodiments, the conducting layer provides current spreading for p-doped layer 110.

When electrical energy is applied to epitaxial structure 104, light emitting portion 112 at junction of n-type doped layer 108 and p-type doped layer 110 generates an electron-hole capture phenomenon. As a result, the electrons of light emitting portion 112 will fall to a lower energy level and release energy with a photon mode. In certain embodiments, light emitting portion 112 is a single quantum well (SQW) or a multiple quantum well (MQW) structure capable of restricting a spatial movement of the electrons and the holes. Thus, a collision probability of the electrons and the holes is increased so that the electron-hole capture phenomenon occurs easily, thereby enhancing light emitting efficiency.

When a voltage is applied between n-type doped layer 108 and p-type doped layer 110, an electric current flows between electrodes coupled to the n-type doped layer and the p-type doped layer through epitaxial substrate 102 and is horizontally distributed in epitaxial structure 104. Thus, a number of photons are generated by a photoelectric effect in epitaxial structure 104. LED 100 emits light from epitaxial structure 104 due to the horizontally distributed electric current.

FIG. 3 depicts a simplified side-view representation of the embodiment of LED 100 showing substrate 102, n-doped layer 108, p-doped layer 110, and light emitting layer 112. In certain embodiments, LED 100 is a horizontal LED. For example, light emitting layer 112 may be formed to emit blue light, green light, or red light.

In certain embodiments described herein, two LEDs 100 may be combined (e.g., stacked) to form an LED module emitting light beams with the same wavelengths. In certain embodiments described herein, two LEDs 100 may be combined (e.g., stacked) to form an LED module emitting two separate light beams with different wavelengths. For example, a green light emitting LED may be stacked with a blue light emitting LED in a single LED module such that the LED emits the green light beam separately from the blue light beam. FIGS. 4-10 depict various steps in an embodiment of a process for forming a stacked LED module with two LEDs 100. FIG. 4 depicts a side-view representation of an embodiment of bottom LED 100A to be used in the stacked LED module. In certain embodiments, bottom LED 100A includes substrate 102A and epitaxial structure 104A. Epitaxial structure 104A includes n-doped layer 108A, p-doped layer 110A, and light emitting layer 112A. Substrate 102A may be a sapphire substrate and light emitting layer 112A may be a green light emitting layer. Thus, in certain embodiments, bottom LED 100A is a green light emitting LED. In some embodiments, substrate 102A includes a reflective layer on the upper surface of the substrate. The reflective layer may include a distributed Bragg reflector (DBR), an omni-directional reflector (ODR), silver, aluminum, titanium, and/or other reflective metals.

In certain embodiments, one or more posts 116 are formed on top of epitaxial structure 104A (e.g., on top of p-doped layer 110A), as shown in FIG. 4. In some embodiments, one or more posts 116 are formed on a conducting layer (e.g., an ITO layer) formed on top of p-doped layer 110A. Posts 116 may be formed using one or more deposition processes. In some embodiments, posts are formed as part of p-doped layer 110A (e.g., the posts are formed from the p-doped layer material after growth or deposition of the p-doped layer). In certain embodiments, posts 116 are made of metal or conductive material that is deposited on p-doped layer 110A. For example, posts 116 may be made of indium tin oxide (ITO). Providing posts 116 from metal or conductive material that are in ohmic contact with p-doped layer 110A may increase current spreading in the p-doped layer. In some embodiments, posts 116 are made of insulating material (e.g., silicon oxide).

In some embodiments, the top surface of bottom LED 100A is flat. Posts 116 may be formed with substantially similar heights on the flat top surface of bottom LED 100A. In such embodiments, substrate 102A of bottom LED 100A may be a patterned substrate and/or the bottom surface of n-doped layer 108A or undoped layer 114 may be patterned. Patterning substrate 102A and/or the bottom surface of n-doped layer 108A, or undoped layer 114, may increase light extraction from the stacked LED module.

In some embodiments, the top surface of bottom LED 100A is roughened (e.g., the top surface of p-doped layer 110A is roughened). Roughening the top surface of bottom LED 100A may increase light extraction from the stacked LED module. Having a rough top surface may, however, produce varying heights for posts 116 formed on p-doped layer 110A.

In certain embodiments, to form the LED module, the top surface of the top LED may be bonded to a temporary substrate. FIG. 5 depicts a side-view representation of an embodiment of top LED 100B to be used in the stacked LED module. In certain embodiments, top LED 100B includes substrate 102B and epitaxial structure 104B. Epitaxial structure 104B includes n-doped layer 108B, p-doped layer 110B, and light emitting layer 112B. Substrate 102B may be a sapphire substrate and light emitting layer 112B may be a blue light emitting layer. Thus, in certain embodiments, top LED 100B is a blue light emitting LED.

In certain embodiments, the top surface (the surface opposite substrate 102B) of top LED 100B is coupled (e.g., bonded) to temporary substrate 120 with adhesive layer 122. Temporary substrate 120 may be a glass or ceramic substrate. Adhesive layer 122 may include materials such as, but not limited to, epoxy glue, wax, SOG (spin-on-glass), photoresist, monomer, polymer (e.g., polyimide), benzocyclobutene (BCB), or any glue type material known in the art for bonding GaN layers to ceramic or glass layers.

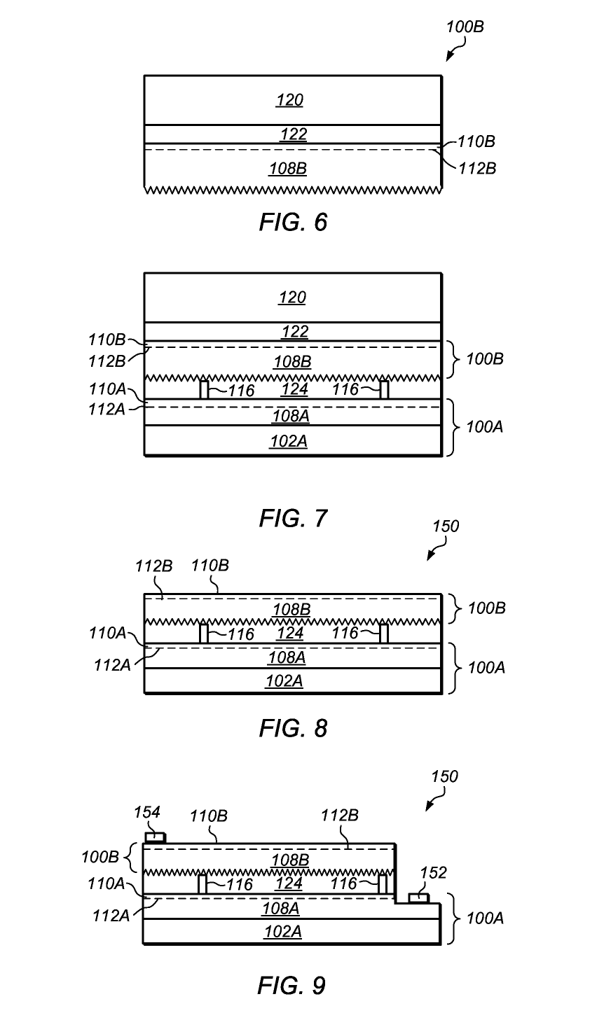

Following bonding of top LED 100B to temporary substrate 120, substrate 102B is removed from the bottom of the top LED to expose the bottom surface of the top LED, as shown in FIG. 6. Substrate 102B may be removed using, for example, a laser lift-off (LLO) process. Removing substrate 102B exposed the bottom surface of n-doped layer 108B. In some embodiments, if there is an undoped layer between substrate 102B and n-doped layer 108B (e.g., undoped layer 114 depicted in FIG. 2), the undoped layer is also removed to expose the n-doped layer. N-doped layer 108B is exposed to allow for electrical connection to the n-doped layer using electrodes. In some embodiments, the exposed bottom surface of n-doped layer 108B is roughened, as shown in FIG. 6. For example, the bottom surface may be roughened using a wet etching process.

Following removal of substrate 102B, top LED 100B is bonded to bottom LED 100A, as shown in FIG. 7. To bond top LED 100B to bottom LED 100A, the exposed bottom surface of n-doped layer 108B may be bonded to the upper surface of p-doped layer 110A of bottom LED 100A (e.g., the top surface of the bottom LED opposite substrate 102A). In certain embodiments, the exposed bottom surface of n-doped layer 108B is bonded to the upper surface of the conducting layer formed on top of p-type doped layer 110A of bottom LED 100A. The conducting layer may include, for example, indium tin oxide (ITO). In certain embodiments, top LED 100B is bonded to bottom LED 100A with adhesive layer 124. In certain embodiments, adhesive layer 124 is a glue material with a low refractive index (e.g., refractive index of about 1.5). For example, adhesive layer 124 may include materials such as, but not limited to, SOG (spin-on-glass), photoresist, polymer (e.g., polyimide), or benzocyclobutene (BCB). Using adhesive layer 124 to bond top LED 100B to bottom LED 100A allows the LEDs to be bonded without the use of a substrate between the LEDs. Having no substrate between the LEDs improves light extraction from the stacked LED module.

Posts 116 may have a height that is the desired (selected) thickness of adhesive layer 124. Posts 116 (formed on p-doped layer 110A) contact the surface of n-doped layer 108B of top LED 100B such that the posts define the distance between the doped layers. Posts 116 maintain the distance between p-doped layer 110A and n-doped layer 108B during the bonding process using adhesive layer 124. In certain embodiments, posts 116 maintain the distance between the conducting layer formed on top of p-doped layer 110A and n-doped layer 108B during the bonding process using adhesive layer 124. Thus, the height of posts 116 determines the thickness of adhesive layer 124. In certain embodiments, surface roughness on n-doped layer 108B provides a plurality of peaks that increase the contact area between the n-doped layer and posts 116. In some embodiments, posts 116 are formed on the bonding surface of top LED 100B instead of bottom LED 100A. For example, posts 116 may be formed on the bonding surface of top LED 100B after removal of substrate 102B. In some embodiments, posts 116 are formed from substrate 102B (e.g., by removing portions of the substrate).

Following bonding of top LED 100B to bottom LED 100A, temporary substrate 120 and adhesive layer 122 are removed from the top LED to form stacked LED module 150, as shown in FIG. 8. Temporary substrate 120 and adhesive layer 122 may be removed using, for example, a LLO process, an acid etching process, or another suitable etching process. Forming stacked LED module 150 with posts 116 in adhesive layer 124 provides a high alignment tolerance (even without alignment) during the bonding/stacking process steps. For example, the alignment tolerance may be improved with respect to processes that stack LEDs using pad-to-pad bonding techniques.

In certain embodiments, stacked LED module 150 is formed to emit light at a single wavelength. For example, in some embodiments, bottom LED 100A and top LED 100B emit light with the same wavelength to provide a high voltage stacked LED module. In some embodiments, light from bottom LED 100A and top LED 100B is combined to emit light at the single wavelength. In such embodiments, bottom LED 100A and top LED 100B are stacked and provided power in series with two electrodes. Posts 116 in adhesive layer 124 may be conductive posts (e.g., metal posts or ITO posts) that provide electrical coupling between p-doped layer 110A and n-doped layer 108B.

FIG. 9 depicts a side-view representation of an embodiment of stacked LED module 150 with two electrodes formed on the stacked LED module. Following the removal of temporary substrate 120 and adhesive layer 122, electrodes 152, 154 are formed on stacked LED module 150. Electrodes 152, 154 may be, for example, bonding pads for connection to doped layers in stacked LED module 150. Electrodes 152, 154 may be formed using one or more etch processes (e.g., inductively coupled plasma (ICP) etches) followed by one or more electrode material (e.g., metal) deposition steps. For example, one or more etching processes may be used to remove portions of layers in top LED 100B to form a pad for contacting electrode 152 to n-doped layer 108A. Following the etching process(es), electrode material may be formed (deposited) on the pads such that electrodes 152, 154 are in ohmic contact with their respective underlying layers. In certain embodiments, electrode 154 is formed on p-doped layer 110B without any etching of the p-doped layer. In certain embodiments, electrode 154 is formed on a conducting layer formed on top of p-doped layer 110B. Electrode 152 may be in ohmic contact with n-doped layer 108A and electrode 154 may be in ohmic contact with p-doped layer 110B (or the conducting layer formed on top of the p-doped layer 110B). In certain embodiments, electrodes 152, 154 provide electrical energy to both bottom LED 100A and top LED 100B.

In certain embodiments, stacked LED module 150 is formed to emit light at multiple wavelengths. Thus, bottom LED 100A and top LED 100B may emit light with different wavelengths. For example, light emitting layer 112A may emit light with a longer wavelength (e.g., green light) than light emitted from light emitting layer 112B (e.g., blue light). In such embodiments, bottom LED 100A and top LED 100B are stacked and are provided powered in parallel with two sets of electrodes that are physically and electrically isolated such that the sets of electrodes can be independently biased. Posts 116 in adhesive layer 124 may be insulating posts (e.g., silicon oxide) to inhibit electrical coupling between p-doped layer 110A and n-doped layer 108B through the posts.

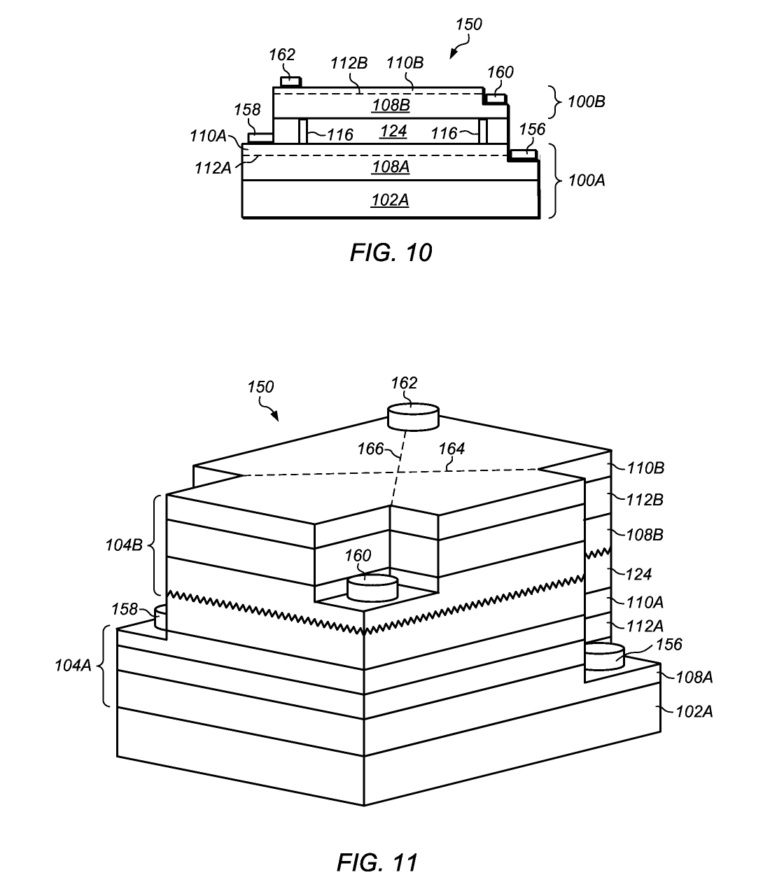

FIG. 10 depicts a side-view representation of an embodiment of stacked LED module 150 with four electrodes formed on the stacked LED module. Following removal of temporary substrate 120 and adhesive layer 122, electrodes 156, 158, 160, 162 are formed on stacked LED module 150. Electrodes 156, 158, 160, 162 may be, for example, bonding pads for connection to doped layers in stacked LED module 150. Electrodes 156, 158, 160, 162 may be formed using one or more etch processes (e.g., inductively coupled plasma (ICP) etches) followed by one or more electrode material (e.g., metal) deposition steps. For example, one or more etching processes may be used to remove portions of layers in top LED 100B and bottom LED 100A to form pads for contacting the electrodes to p-doped layers 110A, 110B (or a conducting layer formed on top of the p-doped layers) and n-doped layers 108A, 108B. Following the etching process(es), electrode material may be formed (deposited) on the pads such that electrodes 156, 158, 160, 162 are in ohmic contact with their respective underlying layers. For example, electrode 156 is in ohmic contact with n-doped layer 108A, electrode 158 is in ohmic contact with p-doped layer 110A (or the conducting layer formed on top of p-doped layer 110A), electrode 160 is in ohmic contact with n-doped layer 108B, and electrode 162 is in ohmic contact with p-doped layer 110B (or a conducting layer formed on top of p-doped layer 110B). In certain embodiments, electrodes 156, 158 provide electrical energy to bottom LED 100A and electrodes 160, 162 provide electrical energy to top LED 100B.

In certain embodiments, electrodes 156, 158, 160, 162 are formed such that the electrodes face the same direction, as shown in FIG. 10. For example, the top surfaces of electrodes 156, 158, 160, 162 may face away from substrate 102A (e.g., the contact surfaces of the electrodes are on the upper surface of stacked LED module 150). With the top (exposed) surfaces of electrodes 156, 158, 160, 162 facing away from substrate 102A, connections (e.g., bonds) may be made to the electrodes from the same side (e.g., the upper side) of stacked LED module 150. Making connections to electrodes 156, 158, 160, 162 on the upper surface of stacked LED module 150 may reduce the size of an optical device derived from the stacked LED module.

In certain embodiments, electrodes 156, 158 are physically and electrically isolated from electrodes 160, 162 to allow for independent control of bottom LED 100A and top LED 100B. For example, each electrode 156, 158, 160, 162 may be located at or near one of the four corners of stacked LED module 150. FIG. 11 depicts a perspective view of an embodiment of stacked LED module 150 with each electrode 156, 158, 160, 162 located at one of the corners of the stacked LED module.

As shown in FIGS. 11, electrode 156 may be located at or near a first corner of bottom LED 100A and electrode 158 may be located at or near a second corner of the bottom LED that is opposite the first corner. Electrodes 160, 162 may be located at or near opposite third and fourth corners, respectively, of top LED 100B. Thus, electrodes 156, 158 are located at or near opposite corners along diagonal 164 of bottom LED 100A while electrodes 160, 162 are located at or near opposite corners along diagonal 166 of top LED 100B. As shown in FIG. 11, diagonal 164 crosses diagonal 166.

Locating the electrodes for each of bottom LED 100A and top LED 100B on separate diagonals that cross each other allows for independent control of the epitaxial structures of the bottom and top LEDs. For example, epitaxial structure 104A of bottom LED 100A may be biased independently from epitaxial structure 104B of top LED 100B. Independent biasing of epitaxial structure 104A and epitaxial structure 104B provides independent control of light emitting layers 112A, 112B. Thus, in certain embodiments, light emitting layer 112A and light emitting layer 112B emit different wavelengths of light that are independently controllable. In certain embodiments, light emitting layer 112A emits light with a longer wavelength than light emitted from light emitting layer 112B. For example, light emitting layer 112A may emit green light and be independently controlled from light emitting layer 112B that emits blue light.

Because bottom LED 100A and top LED 100B can be controlled independently, stacked LED module 150 can emit light in a range of wavelengths between the wavelength emitted by the bottom LED and the wavelength emitted by the top LED. For example, at any point during use, stacked LED module 150 may emit light at the wavelength of bottom LED 100A, the wavelength of top LED 100B, or a combination of the wavelengths of the bottom LED and the top LED depending on the biases applied to the bottom LED and the top LED.

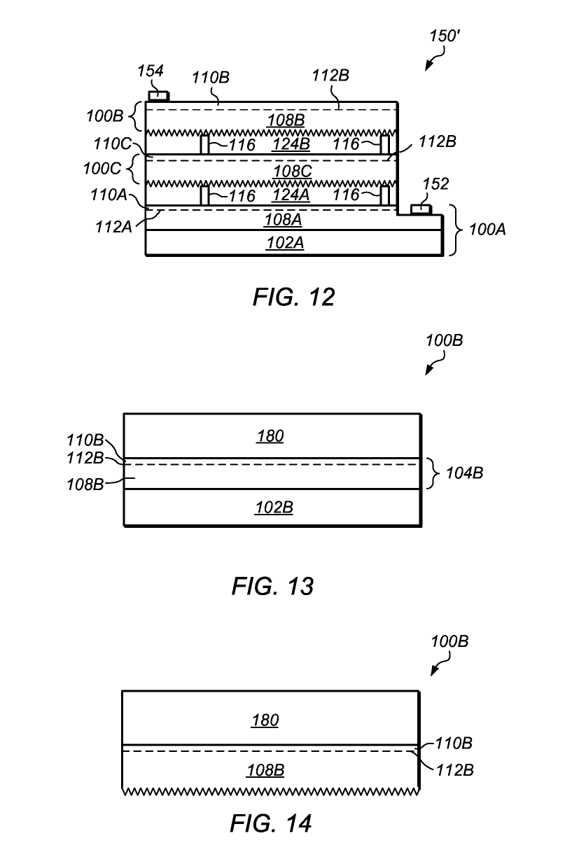

In certain embodiments, stacked LED module 150 includes three LEDs (e.g., a bottom LED, a middle LED, and a top LED). The three LEDs may emit light with the same wavelength or with different wavelengths (e.g., red, blue, and/or green wavelengths). The three LEDs may be provided power in series or parallel to provide either a high voltage LED module emitting light at a single wavelength (powered in series) or a multiple wavelength emitting LED module (powered in parallel). FIG. 12 depicts a side-view representation of an embodiment of stacked LED module 150″ with three LEDs (bottom LED 100A, middle LED 100C, and top LED 100B). As shown in FIG. 12, bottom LED 100A, middle LED 100C, and top LED 100B are stacked and provided power in series with electrodes 152, 154. It is to be understood that bottom LED 100A, middle LED 100C, and top LED 100B may also be stacked and provided power in parallel with three sets of electrodes (one for each LED) that are physically and electrically isolated (such as shown for two stacked LEDs in FIGS. 10 and 11).

As shown in FIG. 12, bottom LED 100A, middle LED 100C, and top LED 100B are stacked and bonded with adhesive layer 124A bonding the bottom LED to the middle LED and adhesive layer 124B bonding the middle LED to the top LED. Bottom LED 100A and middle LED 100C may be bonded with adhesive layer 124A using the various steps in the embodiment of the process for forming stacked LED module 150 from two LEDs described herein (e.g., the embodiment described and depicted in FIGS. 4-8). Similar steps may be used to bond middle LED 100C to top LED 100B using adhesive layer 124B and, for example, a temporary substrate for the top LED.

In certain embodiments, posts 116 in adhesive layers 124A, 124B are conductive posts (e.g., ITO or metal) that increase current spreading in p-doped layers 110A and 110C. In certain embodiments, conducting layers (e.g., ITO) are formed on top of p-doped layers 110A and 110C. Using both conductive posts and conducting layers may further increase current spreading in p-doped layers 110A and 110C. Forming stacked LED module 150″ with posts 116 in adhesive layers 124A, 124B provides a high alignment tolerance (even without alignment) during the bonding/stacking process steps. For example, the alignment tolerance may be improved with respect to processes that stack LEDs using pad-to-pad bonding techniques.

In certain embodiments, stacked LED module 150, formed in the process embodiment described and depicted in FIGS. 4-8, is flipped upside down and coupled to a conductive substrate. Thus, the flipped stacked LED module has an NPNP (n-doped layer above p-doped layer, above n-doped layer, above p-doped layer) structure versus the PNPN (p-doped layer above n-doped layer, above p-doped layer, above n-doped layer) structure of stacked LED module 150 depicted in FIG. 8. FIGS. 13-16 depict various steps in an embodiment of a process for forming a NPNP stacked LED module with two LEDs.

In certain embodiments, to form the NPNP stacked LED module, the top surface of the top LED is bonded to a conductive substrate. FIG. 13 depicts a side-view representation of an embodiment of top LED 100B bonded to conductive substrate 180. In certain embodiments, top LED 100B includes substrate 102B and epitaxial structure 104B. Epitaxial structure 104B includes n-doped layer 108B, p-doped layer 110B, and light emitting layer 112B. Substrate 102B may be a sapphire substrate and light emitting layer 112B may be a blue light emitting layer. Thus, in certain embodiments, top LED 100B is a blue light emitting LED.

In certain embodiments, the top surface (the surface of p-doped layer 110B) of top LED 100B is coupled (e.g., bonded) to conductive substrate 180. Conductive substrate 180 may be, for example, a metal or a silicon substrate. Conductive substrate 180 may be bonded to p-doped layer 110B using, for example, eutectic bonding. In some embodiments, conductive substrate 180 is formed on p-doped layer 110B using, for example, an electroplating process.

Following coupling of top LED 100B to conductive substrate 180, substrate 102B is removed from the bottom of the top LED to expose the bottom surface of the top LED, as shown in FIG. 14. Substrate 102B may be removed using, for example, a laser lift-off (LLO) process. Removing substrate 102B exposed the bottom surface of n-doped layer 108B. In some embodiments, if there is an undoped layer between substrate 102B and n-doped layer 108B, the undoped layer is also removed to expose the n-doped layer. In some embodiments, the exposed bottom surface of n-doped layer 108B is roughened, as shown in FIG. 14. For example, the bottom surface may be roughened using a wet etching process.

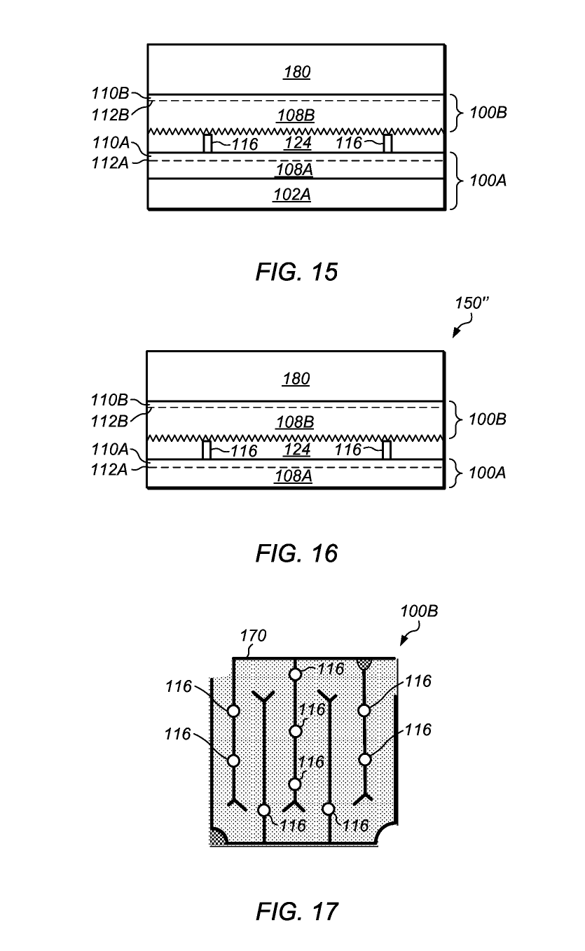

Following removal of substrate 102B, top LED 100B is bonded to bottom LED 100A (shown in FIG. 4), as shown in FIG. 15. To bond top LED 100B to bottom LED 100A, the exposed bottom surface of n-doped layer 108B may be bonded to the upper surface of p-doped layer 110A of bottom LED 100A (e.g., the top surface of the bottom LED opposite substrate 102A). In certain embodiments, the exposed bottom surface of n-doped layer 108B may be bonded to the conducting layer formed on top of the upper surface of p-doped layer 110A of bottom LED 100A. In certain embodiments, top LED 100B is bonded to bottom LED 100A with adhesive layer 124 and posts 116 in the adhesive layer.

Following bonding of top LED 100B to bottom LED 100A, substrate 102A may be removed from the bottom LED to form stacked LED module 150″, as shown in FIG. 16. Substrate 102A may be removed using, for example, a LLO process, an acid etching process, or another suitable etching process. Stacked LED module 150″, as shown in FIG. 16, may be flipped upside down to form a NPNP stacked LED module with conductive substrate 180 as the bottom of the stacked LED module. One or more electrodes may be formed on stacked LED module 150″, as described herein to provide power to bottom LED 100A and top LED 100B. In certain embodiments, bottom LED 100A and top LED 100B are stacked and provided power in series. Bottom LED 100A and top LED 100B may emit light with the same wavelength to provide a high voltage stacked LED module. Posts 116 in adhesive layer 124 may be conductive posts (e.g., ITO or metal posts) that provide electrical coupling between p-doped layer 110A and n-doped layer 108B.

In some embodiments, stacked LED module 150″, is formed to emit light at multiple wavelengths. Bottom LED 100A and top LED 100B may emit light with different wavelengths. For example, light emitting layer 112A may emit light with a longer wavelength (e.g., green light) than light emitted from light emitting layer 112B (e.g., blue light). In such embodiments, bottom LED 100A and top LED 100B are stacked and are provided powered in parallel with two sets of electrodes that are physically and electrically isolated such that the sets of electrodes can be independently biased. Posts 116 in adhesive layer 124 may be insulating posts (e.g., silicon oxide) to inhibit electrical coupling between p-doped layer 110A and n-doped layer 108B through the posts.

In some embodiments described herein, either bottom LED 100A or top LED 100B may be flipped before bonding the LEDs to form a stacked LED module with either PNNP structure or NPPN structure. For example, either bottom LED 100A or top LED 100B may be flipped and bonded to a temporary substrate before being bonded to the other LED. It is to be understood that the process for forming either the PNNP structure or the NPPN structure may include other elements not described herein but known in the art. The resulting PNNP structure or NPPN structure may, however, include at least one adhesive layer with posts (e.g., posts 116) in the adhesive layer. In certain embodiments, the posts in the adhesive layer of either the PNNP structure or the NPPN structure are insulating posts (e.g., silicon oxide posts) to inhibit electrical coupling between the bonded layers and to allow for providing power in parallel to the individual LEDs in the structure. In certain embodiments, the posts in the adhesive layer of either the PNNP structure or the NPPN structure are conductive posts to allow electrical coupling between the bonded layers and to allow for providing common electrodes.

In certain embodiments described herein, posts 116 are positioned under an electrode patterned formed on top LED 100B. FIG. 17 depicts a top view representation of electrode pattern 170 on top LED 100B showing the location of posts 116 under the electrodes in the pattern. Locating posts 116 under the electrodes in pattern 170 reduces the amount of light shielding produced by the posts as the posts are located under the electrode pattern that also produces light shielding. Additionally, locating posts 116 under only the electrodes in pattern 170 reduces the number of posts used and provides less light shielding than if additional posts are located under other areas of top LED 100B.

While FIGS. 4-16 depict various steps in embodiments of one or more processes for forming stacked LED modules with two or three LEDs, it is to be understood that one or more of the steps depicted and described herein may be used in a process to form multiple stacked LED modules on a single substrate or multiple substrates. For example, the steps depicted and described herein may be used in a wafer-to-wafer bonding process with multiple bottom LEDs formed on a first wafer bonded to multiple top LEDs formed on a second, temporary wafer.

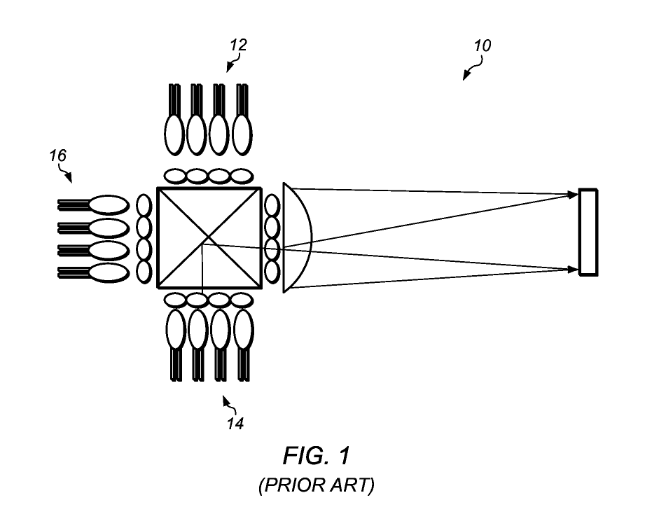

In some embodiments, one or more of the stacked LED modules described herein are used in a light projector system. For example, stacked LED modules that provide power to the LEDs in parallel may be used as the optical engine, or as part of the optical engine, in a light projector (source) system similar to light source system 10, depicted in FIG. 1. Using stacked LED modules 150 in the light projector system may reduce the size of the system by combining two different wavelength light sources into a single set of LED modules (e.g., stacked LED modules 150). Combining the two different wavelength light sources and reducing the size of the light projector system may potentially lower the cost for making and operating the light projector system.

It is to be understood the invention is not limited to particular systems described which may, of course, vary. It is also to be understood that the terminology used herein is for the purpose of describing particular embodiments only, and is not intended to be limiting. As used in this specification, the singular forms “a”, “an” and “the” include plural referents unless the content clearly indicates otherwise. Thus, for example, reference to “a device” includes a combination of two or more devices and reference to “a material” includes mixtures of materials.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A semiconductor light emitting device, comprising:
a substrate;
a first epitaxial structure over the substrate, the first epitaxial structure comprising a first doped layer, a first light emitting layer, and a second doped layer, wherein the first doped layer comprises a first dopant type and the second doped layer comprises a second dopant type;
a second epitaxial structure comprising a third doped layer, a second light emitting layer, and a fourth doped layer;
an adhesive layer between the first epitaxial structure and the second epitaxial structure;
one or more posts located in the adhesive layer; and
an electrode pattern located on an upper surface of the second epitaxial structure, wherein the posts are located under electrodes in the electrode pattern.

2. The device of claim 1, wherein the first epitaxial structure comprises the first light emitting layer above the first doped layer and the second doped layer above the first light emitting layer, wherein the second epitaxial structure comprises the second light emitting layer above the third doped layer and the fourth doped layer above the second light emitting layer, and wherein the adhesive layer is between the second doped layer of the first epitaxial structure and the third doped layer of the second epitaxial structure.

3. The device of claim 1, wherein the third doped layer comprises the first dopant type and the fourth doped layer comprises the second dopant type.

4. The device of claim 1, wherein the third doped layer comprises the second dopant type and the fourth doped layer comprises the first dopant type.

5. The device of claim 1, wherein the first dopant type comprises n-type dopant and the second dopant type comprises p-type dopant.

6. The device of claim 1, wherein the posts comprise conductive material or insulating material.

7. The device of claim 1, wherein a height of one or more of the posts determines a thickness of the adhesive layer.

8. The device of claim 1, wherein the posts electrically couple the second doped layer of the first epitaxial structure and the third doped layer of the second epitaxial structure.

9. The device of claim 1, wherein the posts connect the first epitaxial structure and the second epitaxial structure.

10. The device of claim 1, wherein a surface of the second epitaxial structure bonded to the adhesive layer comprises a roughened surface.

11. The device of claim 1, further comprising a first electrode coupled to the fourth doped layer and a second electrode coupled to the first doped layer.
